(19) United States
(12) Patent Application Publication
(10) Pub. No.: US 2001/0051408 A1
(43) Pub. Date: Dec. 13, 2001

(54) METHOD FOR PROVIDING IMPROVED STEP COVERAGE OF DEEP TRENCHES AND USE THEREOF

(76) Inventor: YIH-SONG CHIU, CHU-DANG CITY (TW)

Correspondence Address: RICHARD J PACIULAN, LADAS & PARRY, 5670 WILSHIRE BOULEVARD, SUITE 2100, LOS ANGELES, CA, 900365679

(21) Appl. No.: 09/412,830

(22) Filed: Oct. 5, 1999

(30) Foreign Application Priority Data
Apr. 20, 1999 (TW) 88106286

(51) Int. Cl. H01L 27/108; H01L 29/76; H01L 29/94

(52) U.S. Cl. 438/243; 438/386; 257/301

(57) ABSTRACT

Disclosed is a method for providing improved step coverage of deep trenches. A hard mask which constitutes a bottom silicon oxide layer and a top silicon nitride layer is formed on a substrate and patterned to form a opening. A deep trench extending into the substrate is formed through the opening. After both hard mask and substrate are patterned, HF vapor is performed to selectively etch away portions of hard mask. Then a deep trench with a ladder-like hard mask which has improved step coverage is obtained.

### BACKGROUND OF THE INVENTION

1. Field of the Invention

The present invention relates to the deposition of films into deep trenches, and more particularly to improving the step coverage of films deposited into deep trenches.

2. Description of the Related Arts

Deep trenches are common structures in semiconductor devises, especially used for fabricating trench capacitors. As dimensions continue to be scaled down to the submicron level, the deep trench opening shrinks in size while the depth of the deep trench remains the same. In other word, the aspect ratio of deep trenches increases as semiconductor devises become more densely packed.

A conventional method of depositing a film in a deep trench is described as follows.

Referring to FIG. 1, a silicon substrate 10 having a silicon oxide layer 12 and a silicon nitride layer 14 formed thereon is provided. The silicon oxide layer 12 and the silicon nitride layer 14 are patterned by a standard photolithography technique and an anisotropic technique to form an opening 16.

Once the silicon oxide layer 12 and the silicon nitride layer 14 are patterned, a deep trench 18 extending into the substrate 10 from the top surface of the substrate 10 is defined by a standard photolithography technique and an anisotropic etch method, such as reactive ion etch, using the patterned silicon oxide layer 12 and silicon nitride layer 14 as a hard mask. FIG. 2 illustrates the deep trench 18. Then a conductive layer 19 is deposited into the deep trench 18. Unfortunately, the deposition of the conductive layer 19 produces poor step coverage into a deep trench 18 having high aspect ratio (as shown in FIG. 3). During the conductive layer 19 deposition, the layer builds quickly on the lip of the patterned silicon nitride layer 14. The faster deposition of the layer creates a bulge into the mouth of the trench 18, sheltering the lower portions and thus even further slowing down deposition in the bottom corners of the trench. Where the trench has an aspect ration of 1.0 or greater, the deposited layer is especially to close the trench. Voids are sometimes created in filling the trench.

Furthermore, the deep trench 18 is partially isotropically defined by the anisotropic technique (such as a reactive ion etch), therefore the patterned hard mask forms a eave-like structure at the opening of the deep trench 18 and the problem of poor step coverage becomes more serious.

Some prior arts describe methods of improving step coverage of the deep trench. Before the conductive layer 19 is deposited, the exposed portion of eave-like hard mask is selectively removed using a mixture containing HF liquid and glycerol. But when the mixture is used, problems of poor cleanliness and materials used cause increase costs.

### SUMMARY OF THE INVENTION

It is therefore an object of the invention to provide a method of obtaining improved step coverage for a deep trench film deposition. The method uses HF vapor to selectively remove the eave-like hard mask until the lip of the trench is exposed. As a result, the sidewall of hard mask becomes ladder-like, and the deposition of films produces good step coverage into a deep trench having high aspect ratio.

According to the object of the invention, a method of providing improved step coverage of a trench is disclosed. A semiconductor substrate having a surface is provided. A silicon oxide layer is formed on said semiconductor substrate. A silicon nitride layer is formed on said silicon oxide layer. The silicon nitride layer and the silicon oxide layer are patterned to form at least one opening there through exposing a portion of said semiconductor surface. The semiconductor substrate is etched through the opening to form a trench extending into said substrate from said surface. Finally, the silicon nitride layer and the silicon oxide layer are treated through the opening using HF vapor until the lip of said deep trench is exposed.

After the deep trench with good step coverage is formed, it should be understood that a trench capacitor can be fabricated using the deep trench. For instance, a bottom electrode is formed in the substrate through the deep trench, a dielectric layer is formed on the deep trench, and finally a top electrode is formed on the dielectric layer and a trench capacitor is formed.

Other objects, features, and advantages of the present invention will become apparent from the following detailed description which makes reference to the accompanying drawings.

### BRIEF DESCRIPTION OF THE DRAWINGS

FIGS. 1 through 3 are cross-sectional views illustrating the fabrication steps of a conventional deep trench;

FIGS. 4 through 7 are cross-sectional views illustrating the fabrication steps of a trench capacitor according to the present invention; and

FIG. 8 is cross-sectional view illustrating the structure of the etching system.

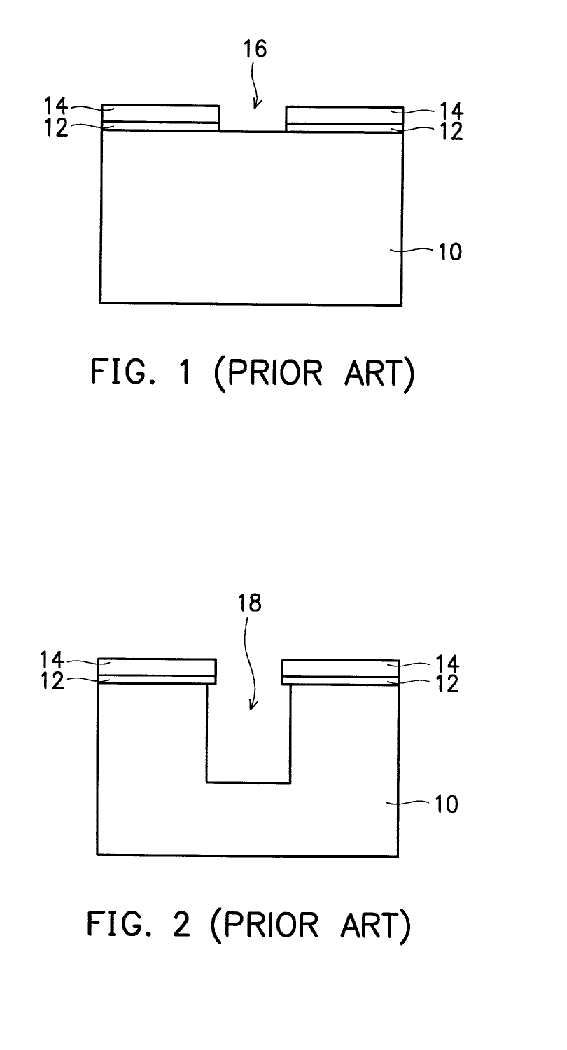

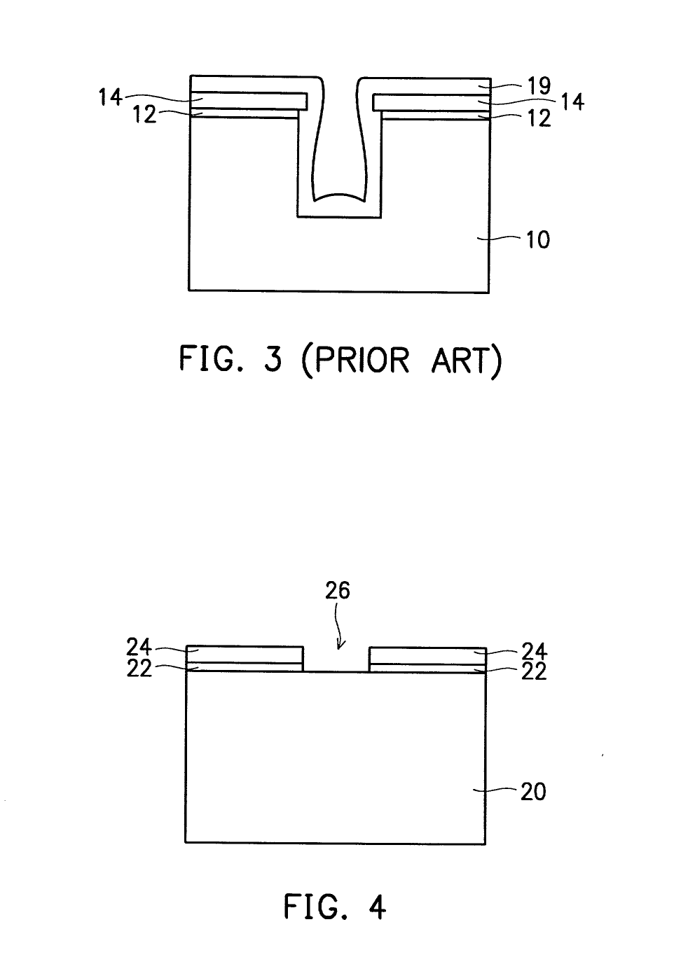

### DETAILED DESCRIPTION OF THE INVENTION

Without intending to limit it in any manner, the present invention will be further illustrated by the following examples.

The present description of preferred embodiments focuses on a deep trench in the semiconductor substrate, it will be understood by those skilled in the art of integrated circuit fabrication that the invention may be applied to depositing contacts between any two levels in an integrated circuit.

FIG. 4 illustrates a starting point for a preferred embodiment of the present invention. A semiconductor substrate 20 is shown in cross-section. The preferred substrate 20 is composed of a P-type single crystal silicon having a <100> crystallographic orientation. A silicon oxide layer 22 is formed on the semiconductor substrate 20 and silicon nitride layer 24 is formed on the silicon oxide layer 20.

The silicon oxide layer 22 is preferably composed of silicon dioxide and formed by any one of a number of known techniques, such as oxidation of the wafer by exposure to steam or dry oxygen at high temperature, chemical vapor deposition, LPCVD method involving reacting pyrolytic oxidation of alkoxy silanes such as TEOS (tetraethylorthosilane), and so forth.

The silicon nitride layer 24 can be formed by known methods such as, for example, CVD methods involving reacting silane and ammonia, with N₂ as the diluent. It is easy to provide favorable dry etch selectivity between silicon and silicon nitride, making silicon nitride useful as an etching mask material. The silicon oxide layer serves as a buffer for the stress induced by the silicon nitride layer 24 on the silicon substrate 20. The silicon oxide layer 22 and the silicon nitride layer 24 together constitute the so-called “hard mask”.

Upon formation of the hard mask, steps for patterning the mask can be performed. The silicon nitride layer 24 and the silicon oxide layer 22 are removed at portions left exposed by a patterned photoresist by reactive ion etching (RIE) using a plasma formed from, for example, CHF₃/CF₄ source gas. An opening 26 through the hard mask is formed to expose portions of surface areas on the silicon substrate 20.

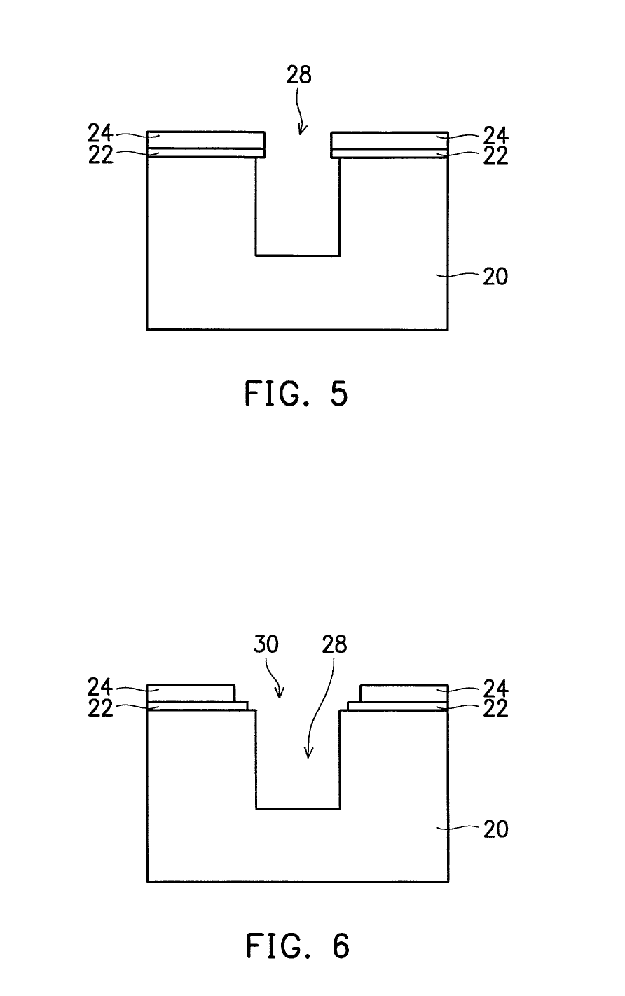

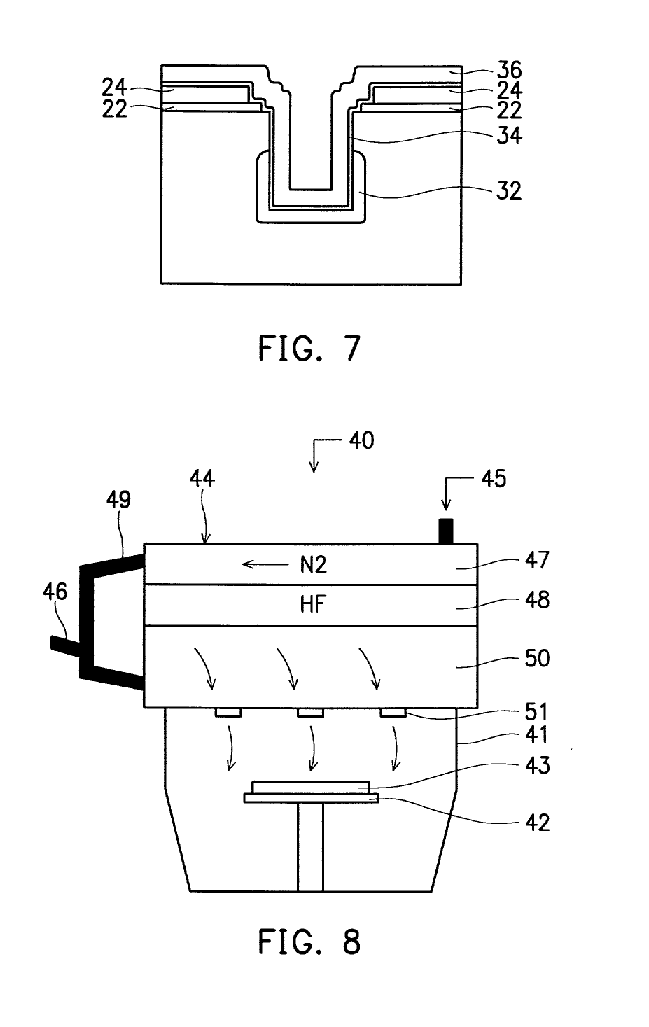

The patterned hard mask is then used to form deep trenches 28 as holes etched into the silicon substrate 20 by an anisotropical technique, such as RIE using a plasma formed form CF₄ source gas. The resulting trench structure is shown in FIG. 5.

However, the deep trench 28 is partially isotropically defined by any kind of anisotropical techniques (i.e. the silicon substrate is partially etched in the lateral direction), thereby the patterned hard mask forms an eave-like structure on the opening of the deep trench 28.

In the following step, the whole silicon substrate 20 is treated with HF vapor. This results in the silicon nitride layer 24 being etched away much more significantly than the silicon dioxide 22 through the opening 26. Thus, the eave-like structure disappears and a ladder-like hard mask is obtained.

After the deep trench 28 with a ladder-like hard mask is obtained, further processes to fabricate a trench capacitor can be preformed. A bottom electrode 32 is formed by ion implantation of conductive dopants such as phosphorus into silicon substrate 20 through the deep trench 28. A dielectric layer 34 is deposited over the deep trench 28, for example, by CVD. The dielectric layer 34 can be composed of a material with a high dielectric constant such as oxide/silicon nitride/oxide (ONO) or Ta₂O₅. Finally, a top electrode 36 is formed over the dielectric layer 34 and a trench capacitor is completed. The top electrode 36 is a conductive layer which can be formed of doped polysilicon, tungsten, tungsten silicide or silicon nitride.

The principal structure of a etching system 40 utilizing HF vapor as the etching gas is shown in FIG. 8. It should be understood that FIG. 8 is a schematic cross-sectional view, comprising following elements: a vapor phase chamber 41, and a etching gas-offering chamber 44 located above the vapor phase chamber 41. The vapor phase chamber 41 contains a hot plate 42 used for heating a wafer 43 thereon. The etching gas-offering chamber 44 contains a first nitrogen source 45 which offers nitrogen serving as carrier gas, a second nitrogen source 46 which offers nitrogen serving as cleaning gas, a first channel 47, a second channel 48 which filled with HF liquid, a third channel 49, and a fourth channel 50, wherein the first channel 47 is ventilated to the second channel 48. A distribution plate 51 has many orifices which nitrogen gas and HF vapor can pass through is located between the vapor gas chamber 41 and the etching gas-offering chamber 45.

After a semiconductor wafer is transferred to the etching system 40, the vapor phase chamber 41 is carefully cleaned in order to maintenance the stability of atmosphere during the etching process. The pre-clean process includes opening the second nitrogen source 46 to pass nitrogen successively through the third channel 49, the fourth channel 50, the distribution plate 51 and finally the vapor phase chamber 41. This prevents the residue of HF vapor or moisture which may disturb the stability of atmosphere existing in the vapor phase chamber 41.

When the pre-clean process is completed, the etching process using HF vapor can be preformed. First, the first nitrogen source 45 is opened and nitrogen carrier gas is released. Then released nitrogen passes through the first channel 47 and carries out HF vapor from the second channel 48. HF vapor carried by nitrogen passes through the third channel 49, the fourth channel 50 and the distribution plate 51, and finally reaches the vapor phase chamber 51 where the wafer is partially etched by HF vapor.

After the etching process is completed, the post-clean process is performed to flush the residue HF off the wafer 43. The step sequence of the post-clean process is the same as that of the pre-clean process.

In this etching step, the temperature of HF liquid in the second channel is the key factor to determine the selectivity ratio with respect to silicon nitride layer and silicon dioxide layer. The preferable temperature of HF liquid is at 22-24° C. and a selectivity ratio of up to 3 can be obtained.

For example, the etching system 40 can be operated with 39.5% HF liquid in the second channel set to a temperature of 22.5° C. and the hot plate set to a temperature of 70° C. Thus, a good selectivity with respect to the silicon nitride layer (15±5 Å/min) and the silicon dioxide layer (lower than 5 Å/min) is obtained. Therefor, after the deep trench 28 with eave-like hard mask 29 is treated with HF vapor for a suitable period of time, sidewalls of the hard mask becomes ladder-like because the removed portion of silicon nitride layer is greater than that of silicon oxide layer through the opening 26. The step coverage of depositing layers into the deep trenches with a ladder-like hard mask is better than that with eave-like hard mask.

According to the present invention, the method has advantages of: (1) good step coverage of deep trenches with a ladder-like hard mask; and (2) low cost due to high cleanliness and less usage of HF vapor (compared to the conventional mixture containing HF liquid and glycerol).

While the invention has been particularly shown and described with the reference to the preferred embodiment thereof, it will be understood by those skilled in the art that various changes in form and details may be made without departing from the spirit and scope of the invention.

What is claimed is:

1. A method of providing improved step coverage of a trench, which comprises the steps of:
(a) providing a semiconductor substrate having a surface;
(b) forming a silicon oxide layer on said semiconductor substrate;
(c) forming a silicon nitride layer on said silicon oxide layer;
(d) patterning said silicon nitride layer and said silicon oxide layer to form at least one opening there through exposing a portion of said semiconductor surface;
(e) etching said semiconductor substrate through said opening to form a trench extending into said substrate from said surface; and
(f) etching said silicon nitride layer and said silicon oxide layer through said opening using HF vapor until exposing the lip of said deep trench.

2. The method as claimed in claim 1, wherein said HF vapor is applied by a carrier gas which goes through a channel filling with HF liquid.

3. The method as claimed in claim 1, wherein said HF liquid is at about 22-24° C.

4. The method as claimed in claim 1, wherein in step (f) said semiconductor substrate is etched on a hot plate.

5. The method as claimed in claim 4, wherein said hot plate is at about 40-80° C.

6. A method of forming a trench capacitor for a DRAM cell, which comprising the steps of:
(a) providing a semiconductor substrate having a surface;
(b) forming a silicon oxide layer on said semiconductor substrate;
(c) forming a silicon nitride layer on said silicon oxide layer;
(d) patterning said silicon nitride layer and said silicon oxide layer to form at least one opening there through exposing a portion of said semiconductor surface;
(e) etching said semiconductor substrate through said opening to form a trench extending into said substrate from said surface;
(f) etching said silicon nitride layer and said silicon oxide layer through said opening using HF vapor until exposing the lip of said deep trench;
(g) forming a bottom electrode into said semiconductor substrate through said deep trench;
(h) forming a dielectric layer over said bottom electrode; and
(i) forming a top electrode over said bottom electrode.

7. The method as claimed in claim 1, wherein said HF vapor is applied by a carrier gas which goes through a channel filling with HF liquid.

8. The method as claimed in claim 1, wherein said HF liquid is at about 22-24° C.

9. The method as claimed in claim 1, wherein in step (f) said semiconductor substrate is etched on a hot plate.

10. The method as claimed in claim 4, wherein said hot plate is at about 40-80° C.
